(19) United States
(12) Patent Application Publication
(10) Pub. No.: US 2023/0074702 A1
(43) Pub. Date: Mar. 9, 2023

(54) DISPLAY DEVICE

(71) Applicant: Japan Display Inc., Tokyo (JP)

(72) Inventors: Shimon ITAKURA, Tokyo (JP); Tomohide OOHIRA, Tokyo (JP); Yasuhiko YAMAGISHI, Tokyo (JP)

(73) Assignee: Japan Display Inc., Tokyo (JP)

(21) Appl. No.: 17/941,038

(22) Filed: Sep. 9, 2022

(30) Foreign Application Priority Data
Sep. 9, 2021 (JP) 2021-146953

(51) Int. Cl. G02F 1/1335; H05K 1/18; G02F 1/1333

(52) U.S. Cl. CPC G02F 1/133601; H05K 1/189; G02F 1/133308; H05K 2201/10136

(57) ABSTRACT

According to one embodiment, a flat portion is provided between a first printed circuit and a second printed circuit, and a wall portion of a frame holds and fixes the first flexible printed circuit and the second flexible printed circuit, and thus the first flexible printed circuit and the second flexible printed circuit extend along the wall portion, and a second curvature of the second flexible printed circuit is smaller than a first curvature of the first flexible printed circuit.

### CROSS-REFERENCE TO RELATED APPLICATIONS

This application is based upon and claims the benefit of priority from Japanese Patent Application No. 2021-146953 filed Sep. 9, 2021, the entire contents of which are incorporated herein by reference.

### FIELD

Embodiments described herein relate generally to a display device.

### BACKGROUND

In recent years, technologies have been developed that use a display panel for dimming in addition to the display panel for image display in order to improve the contrast of display devices.

### BRIEF DESCRIPTION OF THE DRAWINGS

FIG. 1 is an exploded perspective view schematically showing a configuration of a display device including two display panels.

FIG. 2 is a cross-sectional view schematically showing of the display device.

FIG. 3 is a cross-sectional view schematically showing a stacked configuration of a liquid crystal display panel and a dimming panel.

FIG. 4 is an enlarged partial view of the display device shown in FIG. 2.

FIG. 5 is a diagram showing a flexible printed circuit when developed to a plane.

FIG. 6 is a perspective view showing a partial configuration of the display device.

FIG. 7 is a perspective view showing a partial configuration of the display device from a different direction from that of FIG. 6.

FIG. 8 is a diagram illustrating the function of a wiring board.

### DETAILED DESCRIPTION

In general, according to one embodiment, a display device comprises a liquid crystal display panel; a dimming panel; a first flexible printed circuit connected to the liquid crystal display panel; a first circuit element provided on the first flexible printed circuit; a first printed circuit connected to the first flexible printed circuit; a second flexible printed circuit connected to the dimming panel; a second circuit element provided on the second flexible printed circuit; a second printed circuit connected to the second flexible printed circuit; a frame including a wall portion; and a support portion including a flat portion and a plurality of leg portions, wherein the flat portion is provided between the first printed circuit and the second printed circuit, the wall portion holds and fixes the first flexible printed circuit and the second flexible printed circuit, the first flexible printed circuit and the second flexible printed circuit extending along the wall portion, and a second curvature of the second flexible printed circuit is smaller than a first curvature of the first flexible printed circuit.

An object of the embodiments is to provide a display device capable of suppressing degradation of circuit elements.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The following is a detailed description of a display device according to one embodiment with reference to the drawings.

In the embodiments, a first direction X, a second direction Y and a third direction Z are orthogonal to each other, but they may intersect at an angle other than 90 degrees. In the following descriptions, a direction forwarding a tip of an arrow indicating the third direction Z is referred to as “upward” or “above” and a direction forwarding oppositely from the tip of the arrow is referred to as “downward” or “below”. The first direction X, the second direction Y and third direction Z may as well be referred to as an X direction, a Y direction and a Z direction, respectively.

With such expressions “a second member above a first member” and “a second member below a first member”, the second member may be in contact with the first member or may be remote from the first member. In the latter case, a third member may be interposed between the first member and the second member. On the other hand, with such expressions “a second member on a first member” and “a second member on a first member”, the second member is meant to be in contact with the first member.

In addition, it is assumed that there is an observation position to observe the semiconductor substrate on a tip side of an arrow in the third direction Z, and viewing from this observation position toward the X-Y plane defined by the first direction X and the second direction Y is referred to as a planar view. Viewing a cross section of the transistor in an X-Z plane defined by the first direction X and the third direction Z or a Y-Z plane defined by the second direction Y and the third direction Z is referred to as a cross-sectional view.

### Embodiment

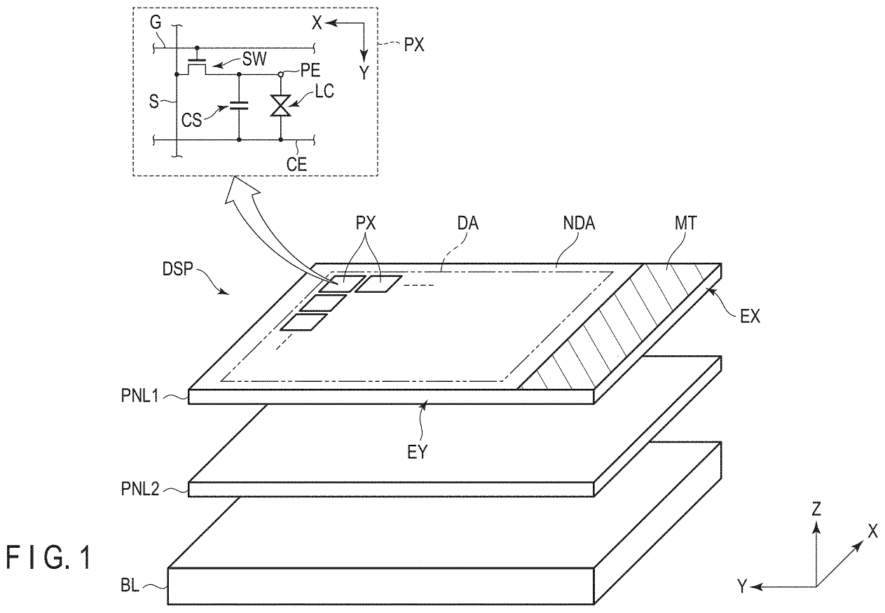

FIG. 1 is an exploded perspective view schematically a display device comprising two display panels. FIG. 1 illustrates a three-dimensional space defined by the first direction X, the second direction Y perpendicular to the first direction X, and the third direction Z perpendicular to the first direction X and the second direction Y.

As shown in FIG. 1, a display device DSP comprises a liquid crystal display panel PNL1, a dimming panel PNL2 and a backlight unit BL. As shown in FIG. 1, the dimming panel PNL2 is disposed between the LCD display panel PNL1 and the backlight unit BL. With this structure, the contrast of images displayed on the liquid crystal display panel PNL1 can be improved.

The liquid crystal display panel PNL1 is, for example, rectangular. In the example illustrated, a short side EX of the liquid crystal display panel PNL1 is parallel to the first direction X, and a long side EY of the liquid crystal display panel PNL1 is parallel to the second direction Y. The third direction Z corresponds to the thickness direction of the liquid crystal display panel PNL1. The main surface of the liquid crystal display panel PNL1 is parallel to the X-Y plane defined by the first direction X and the second direction Y. The liquid crystal display panel PNL1 includes a display area DA and a non-display area NDA located on an outer side of the display area DA. The non-display area NDA includes a terminal area MT on which a driver IC or a flexible printed board is mounted. In FIG. 1, the terminal area MT is indicated by a shaded line.

The display area DA is an area for displaying images and comprises a plurality of pixels PX arranged in a matrix, for example. As shown enlarged in FIG. 1, each pixel PX is arranged in a region partitioned by a scanning lines G and a signal line S, and comprises a switching element SW, a pixel electrode PE, a common electrode CE, a liquid crystal layer LC and the like.

The switching element SW is, for example, a thin-film transistor (TFT) and is electrically connected to the scanning line G and the signal line S. The scanning line G is connected to the switching element SW in each of those pixels PX arranged along the first direction X. The signal line S is electrically connected to the switching element SW in each of those pixels PX arranged along the second direction Y. The pixel electrode PE is electrically connected to the switching element SW. Each of the pixel electrodes PE opposes the common electrode CE, and the liquid crystal layer LC is driven by the electric field generated between the pixel electrode PE and the common electrode CE. A capacitance CS is formed, for example, between an electrode at a potential equal to that of the common electrode CE and another electrode at a potential equal to that of the pixel electrode PE.

The terminal area MT extends along the short side EX of the liquid crystal display panel PNL1. A terminal portion is formed in the terminal area MT, and the liquid crystal display panel PNL1 is electrically connected to an external device such as a flexible circuit board, via the terminal portion.

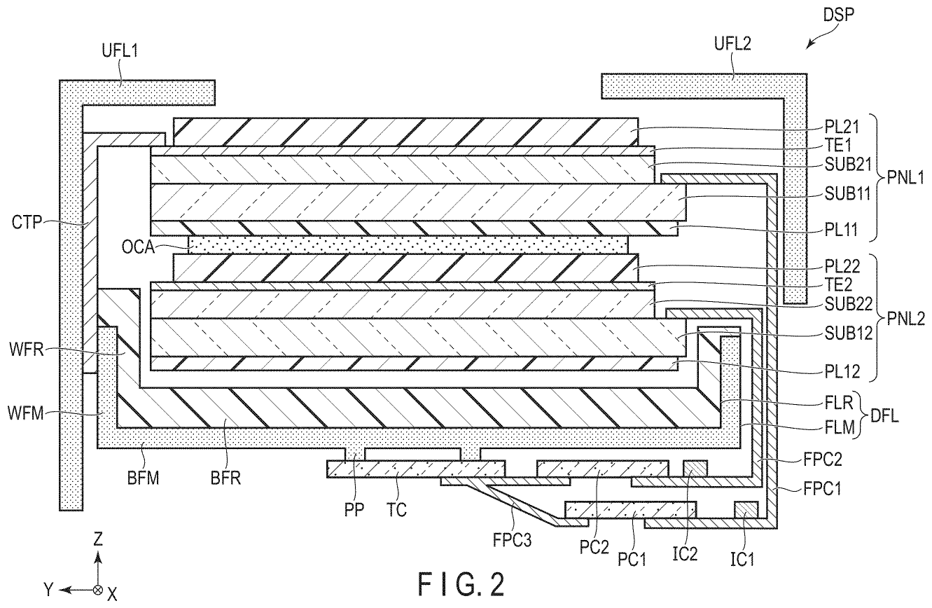

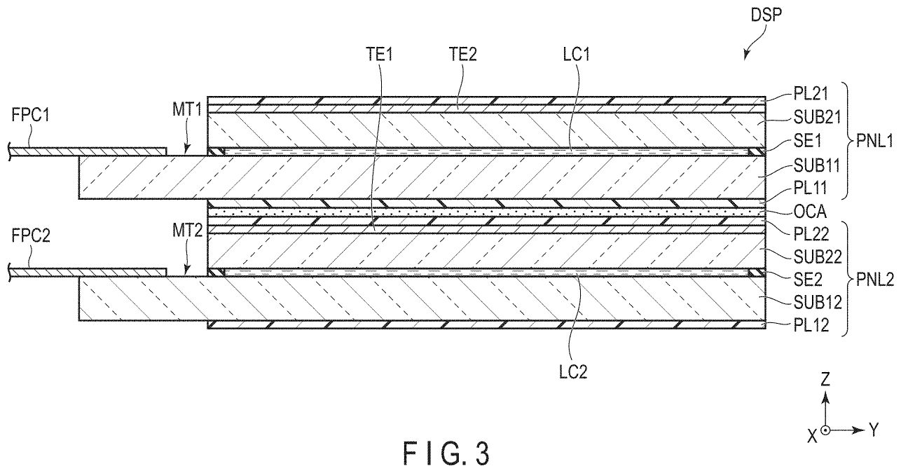

Although the detailed configuration is omitted in FIG. 1, the dimming panel PNL2 is basically the same in configuration as the liquid crystal display panel PNL1. Note that the detailed configurations of the liquid crystal display panel PNL1 and the dimming panel PNL2 will be described later, together with the descriptions of FIGS. 2 and 3.

The backlight unit BL is located below the dimming panel PNL2, and light from the backlight unit BL is controlled for each pixel PX to display images.

FIG. 2 is a cross-sectional view schematically showing an example of the display device. The display device DSP shown in FIG. 2 comprises a liquid crystal display panel PNL1, a dimming panel PNL2, an adhesive layer OCA, a resin frame FLR, a frame FLM, an upper frame UFL1, an upper frame UFL2 and a conductive tape CTP. Although not illustrated in the figure, between the resin frame FLR and the dimming panel PNL2, an illumination device, so-called a back light is provided. The resin frame FLR and the frame FLM constitute the lower frame DFL. In this embodiment, to make it easily understandable, such terms as the “upper frame UFL” and “lower frame DFL” are used, but they may as well be referred to simply as frames.

The upper frame UFL1 and the upper frame UFL2 appear to be separate from each other in the drawing, but they are connected to constitute one frame. The upper frame UFL1 and the upper frame UFL2 are formed of a metal material. The upper frame UFL1 and the upper frame UFL2 may as well be referred to as metal frames.

The liquid crystal display panel PNL1 comprises a first substrate SUB11, a second substrate SUB21, a transparent conductive layer TE1, a first polarizer PL11, a second polarizer PL 21, a first flexible printed circuit FPC1, a first printed circuit PC1 and a first circuit element IC1.

The dimming panel PNL2 comprises a first substrate SUB12, a second substrate SUB22, a transparent conductive layer TE2, a first polarizer PL12, a second polarizer PL22, a second flexible printed circuit FPC2, a second printed circuit PC2 and a second circuit element IC2.

The first flexible printed circuit FPC1 is connected to a terminal end portion of the first substrate SUB11. To the first flexible printed circuit FPC1, the first circuit element IC1 and the first printed circuit PC1 are provided to be in contact therewith. The first circuit element IC1 is provided on the first flexible printed circuit FPC1.

The second flexible printed circuit FPC2 is connected to a terminal portion of the first substrate SUB12. To the second flexible printed circuit FPC2, the second circuit element IC2 and the second printed circuit PC2 are provided to be in contact therewith. The second circuit element IC2 is provided on the second flexible printed circuit FPC2.

Further, a third flexible printed circuit FPC3 is provided in contact with the first printed circuit PC1 and the second printed circuit PC2. The third flexible printed circuit FPC3 is connected to a wiring board TC. Synchronous signals from the wiring board TC are input to the printed circuit PC1 and the second printed circuit PC2 via the third flexible printed circuit FPC3. From the first printed circuit PC1, signals are input to the liquid crystal display panel PNL1 via the first flexible printed circuit FPC1. From the second flexible printed circuit FPC2, signals are input to the dimming panel PNL2 via the second flexible printed circuit FPC2. With these signals, the liquid crystal display panel PNL1 and the dimming panel PNL2 are driven, respectively.

The resin frame FLR includes a bottom portion BFR and a wall portion WFR. The bottom portion BFR has a rectangular shape expanding in the X-Y plane. The wall portion WFR protrudes from an end portion of the bottom portion BFR along the third direction Z.

The frame FLM includes a bottom portion BFM and a wall portion WFM. The bottom portion BFM has a rectangular shape that expands in the X-Y plane. The wall portion WFM protrudes from the end portion of the bottom portion BFM along the third direction Z. The frame FLM is formed of a metal material and is referred to as a metal frame as well.

The resin frame FLR is disposed inside the space formed by the bottom portion BFR of the frame FLM and the wall portion WFR. The bottom portion BFR of the resin frame FLR is in contact with the bottom portion BFM of the frame FLM. The wall portion WFR of the resin frame FLR is in contact with the wall portion WFM of the frame FLM.

In a surface of the bottom portion BFM of the frame FLM, which is not brought into contact with the resin frame FLM, a projecting portion PP is provided. The wiring board TC is provided in contact with the projecting portion PP.

FIG. 3 is a cross-sectional view schematically showing a stacking configuration of the liquid crystal display panel and the dimming panel. As described above, the display device DSP comprises a liquid crystal display panel PNL1 and a dimming panel PNL2. The liquid crystal display panel PNL1 and the dimming panel PNL2 are adhered to each other by, for example, a transparent adhesive layer OCA. Note that the configuration common to the liquid crystal display panel PNL1 and the dimming panel PNL2 is adjusted in position to overlap in plan view and the panels are adhered by the adhesive layer OCA.

The detailed configuration of the liquid crystal display panel PNL1 will now be described.

As shown in FIG. 3, the liquid crystal display panel PNL1 comprises a first substrate SUB11, a second substrate SUB21, a liquid crystal layer LC1, a transparent conductive layer TE1, a first polarizer PL11 and a second polarizer PL21.

The liquid crystal layer LC1 is interposed between the first substrate SUB11 and the second substrate SUB21, and sealed by a sealant SE1. The first polarizer PL11 is disposed below the first substrate SUB11 and the second polarizer PL21 is placed above the second substrate SUB21. A polarization axis of the first polarizer PL11 and a polarization axis of the second polarizer PL21 are, for example, in a cross-Nicol relationship, that is, 90 degrees.

Between the second substrate SUB21 and the second polarizer PL21, a transparent conductive layer TE1 is provided to be in contact with the second substrate SUB21. With the transparent conductive layer TE1, it is possible to prevent the liquid crystal display panel PNL1 from being charged by static electricity. The details will be described later.

The first flexible printed circuit FPC1 is mounted on the terminal area MT1 of the liquid crystal display panel PNL1.

Next, the detailed configuration of the dimming panel PNL2 will be described.

As shown in FIG. 3, the dimming panel PNL2 comprises, as in the case of the liquid crystal display panel PNL1, a first substrate SUB12, a second substrate SUB22, a liquid crystal layer LC2, a transparent conductive layer TE2, a first polarizer PL12 and a second polarizer PL22.

The liquid crystal layer LC2 is interposed between the first substrate SUB12 and the second substrate SUB22 and sealed by a sealant SE2. The first polarizer PL12 is disposed below the first substrate SUB 12 and the second polarizer PL22 is disposed above the second substrate SUB22. The polarization axis of the first polarizer PL12 and the polarization axis of the second polarizer PL 22 are, for example, in a cross-Nicol relationship, that is, 90 degrees. Further, the polarization axis of the first polarizer PL11 of the liquid crystal display panel PNL1 and the polarization axis of the second polarization plate PL22 of the dimming panel PNL2 are set in the same direction.

The transparent conductive layer TE2 is provided between the second substrate SUB22 and the second polarizer PL22 so as to be in contact with the second substrate SUB22. Details of the transparent conductive layer TE2 will be described below.

In the terminal area MT2 of the dimming panel PNL2, the second flexible printed circuit FPC2 is mounted.

The positions of the first circuit element IC1 and the second circuit element IC2 in relation to each other will be described. The first circuit element IC1 and the second circuit element IC2 control the liquid crystal display panel PNL1 and the dimming panel PNL2, respectively. When the display device DSP is operated, the first circuit element IC1 and the second circuit element IC2 generate heat. If the circuit elements are close in distance to each other, the heat generated may cause the circuit elements to deteriorate. Such a configuration is undesirable for the display device DSP as a whole from the standpoint of reliability and the like.

In this embodiment, in order to suppress the degradation of circuit elements, the circuit elements are separated from each other to an extent that the generated heat does not affect each other. In other words, an air layer is placed between adjacent circuit elements. With this structure, the generated heat is dispersed, thereby making it possible to suppress the degradation of the circuit elements.

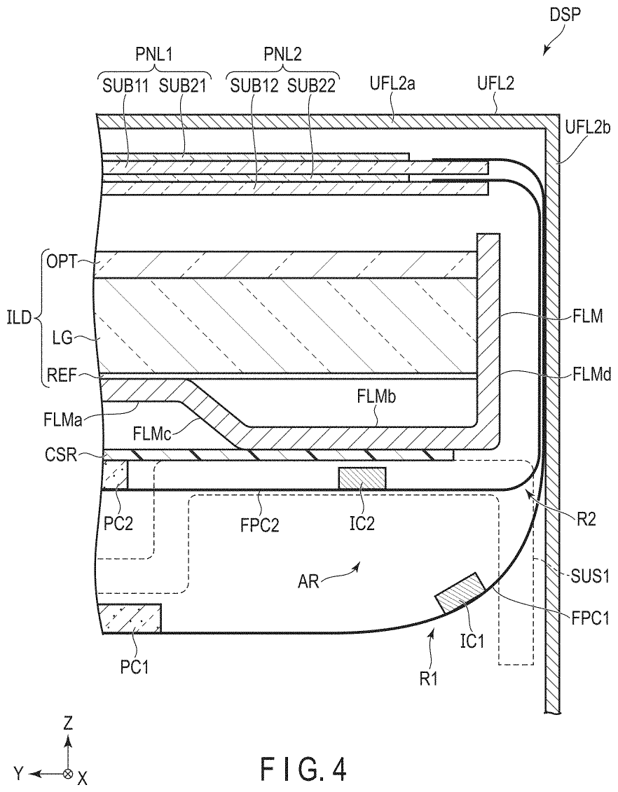

FIG. 4 is an enlarged partial view of the display device shown in FIG. 2. In FIG. 4, in order to make the drawings easier to see, some of the structural elements are omitted. In the display device DSP shown in FIG. 4, the illumination device ILD, the liquid crystal display panel PNL1, the dimming panel PNL2, the upper frame UFL2, the frame FLM, a support portion SUS1, the first flexible printed circuit FPC1, the second flexible printed circuit FPC2, the first circuit element IC1, the second circuit element IC2, the first printed circuit PC1, the second printed circuit PC2 and a resin cushioning material CSR, are shown.

The illumination device ILD comprises a light guide LG, an optical sheet OPT, a reflective member REF and a light emitting element (not shown). The illumination device ILD is provided inside a recess portion formed by the frame FLM. The frame FLM is in contact with a side surface of the light guide LG and a bottom surface of the reflective member REF. In the frame FLM, a portion FLMa in contact with the bottom surface of the light guide LG, and a portion FLMb in contact with an upper surface of the resin cushion material CSR are separated from each other along the third direction Z. Between the two portions FLMa and FLMb, a portion FLMc extending diagonally to connect these portions is provided. The portion in contact with the side surface of the light guide LG is referred to as FLMd.

As described above, in order to avoid the generated heat from each other, the first circuit element IC1 and the second circuit element IC2 are separated from each other by a predetermined distance in an XYZ space. In other words, an air layer AR is provided between the first circuit element IC1 and the second circuit element IC2.

A first curvature R1 of the first flexible printed circuit in which the first circuit element IC1 is provided, and a second curvature R2 of the second flexible printed circuit FPC2, in which the second circuit element IC2 is provided, are different from each other. The first curvature R1 is greater than the second curvature R2.

The upper frame UFL2 includes a flat portion UFL2a expanding along the X-Y plane and a wall portion UFL2b expanding along the X-Z plane. The wall portion UFL2b has the function of pressing to fix the first flexible printed circuit FPC1 extending from the liquid crystal display panel PNL1 and the second flexible printed circuit FPC2 extending from the dimming panel PNL2. The first flexible printed circuit FPC1 and the second flexible printed circuit FPC2 extend along the wall portion UFL2b in the area in contact with the wall portion UFL2b.

Due to the positions of the wall portion UFL2b and the first printed circuit PC1 in relation to each other, the first curvature R1 of the first flexible printed circuit FPC1 is determined. Similarly, due to the positions of the wall portion UFL2b and the second printed circuit PC2 in relation to each other, the curvature R1 of the second flexible printed circuit FPC1 is determined.

The support portion SUS1 is disposed to fix the frame FLM.

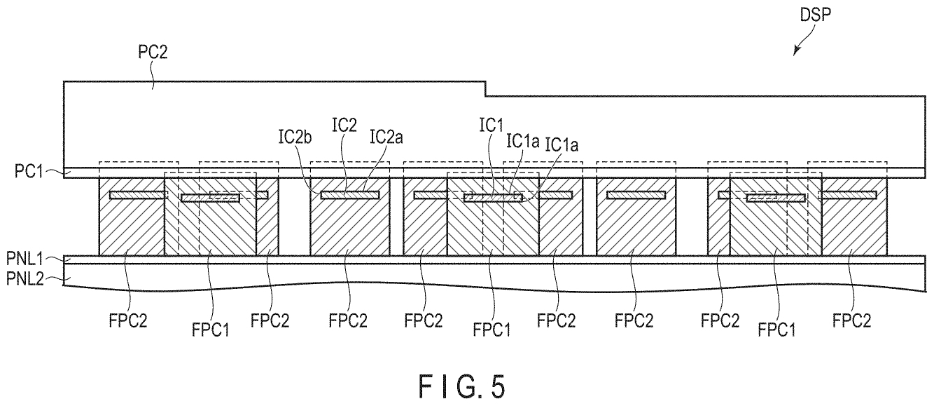

FIG. 5 is a diagram showing the first flexible printed circuit FPC1 and the second flexible printed circuit FPC2, when developed to a plane surface. The dimming panel PNL2 is located on a front side of the page, and the liquid crystal display panel PNL1 is located on a rear side of the page.

The first circuit element IC1 and the second circuit element IC2 are disposed in positions displaced from each other so as not to completely overlap each other. The distance from the first printed circuit PC1 to the first circuit element IC1 and the distance from the first printed circuit PC1 to the second circuit element IC2 do not coincide with each other. A long side IC1a of the first circuit element IC1 and a long side IC2a of the second circuit element IC2 are located in positions where they do not overlap each other. The short side IC1b of the first circuit element IC1 and the short side IC2b of the second circuit element IC2 are disposed in positions where they do not overlap each other.

In FIG. 5, there are three first flexible printed circuits FPC1 and eight second flexible printed circuits FPC2 are provided, but the numbers are not limited to these. The first flexible printed circuits FPC1, which are fewer in number, are provided to be separated from each other. With this structure, the heat propagation between the first circuit elements IC1 can be prevented.

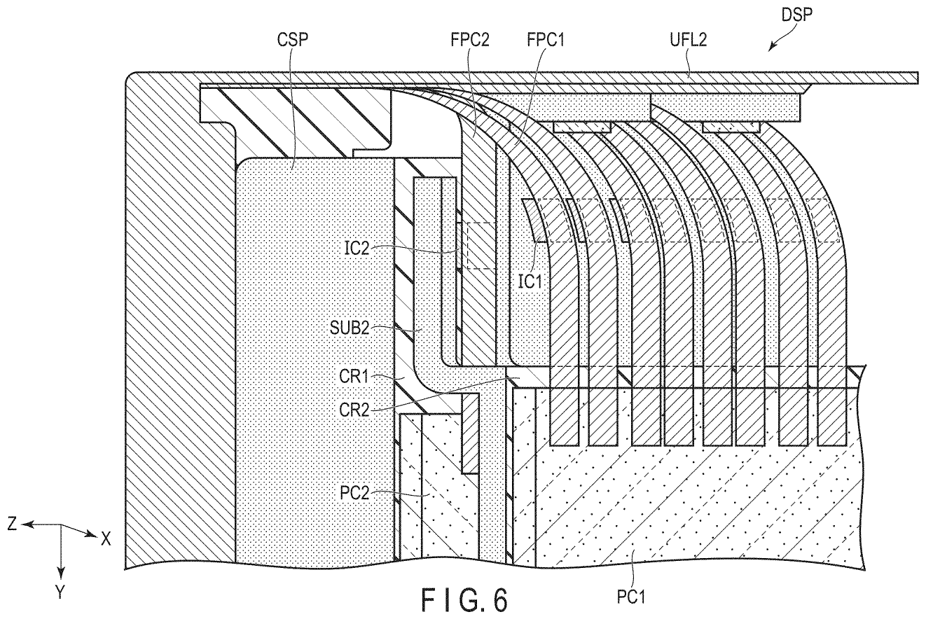

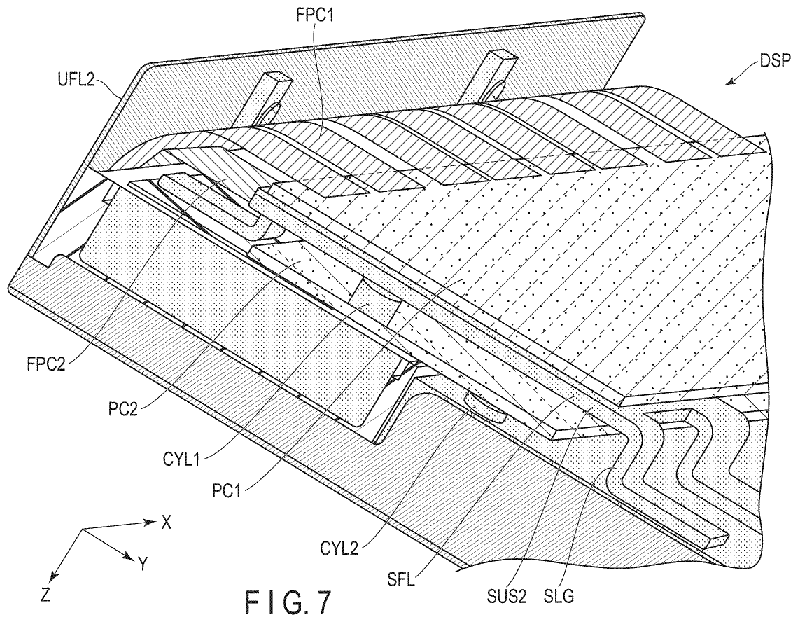

FIG. 6 is a perspective view showing a partial configuration of the display device. FIG. 7 is a perspective view showing a partial configuration of the display device from a different direction from that of FIG. 6.

The first printed circuits PC1 are disposed remote from the respective second printed circuits PC2 by the support portion SUS1. The support portion SUS1 has the so-called table-like structure. The support portion SUS1 includes a flat portion SFL and a plurality of leg portions SLG. Each of the leg portions SLG includes a part extending along the third direction Z. The first printed circuit PC1 is in contact with the flat portion SFL and is disposed apart from the second printed circuit PC2 according to the length of the leg portions SLG along the third direction Z.

Between the first printed circuit PC1 and the support portion SUS1, a cylindrical support portion CYL1 is provided. Between the resin cushioning material CSP and the second printed circuit PC2, a circular support portion CYL2 is provided. The resin cushion material CSP and the support portion SUS1 should be formed, for example, of a foaming resin material.

As shown in FIGS. 2, 4, 6 and 7, the first circuit element IC1 provided on the first flexible printed circuit FPC1 and the second circuit element IC2 provided on the second flexible printed circuit FPC2 are pressed by the wall portion UFL2b of the upper frame UFL2, and disposed along the wall portion UFL2b. The first printed circuit PC1 connected to the first flexible printed circuit FPC1 and the second printed circuit PC2 connected to the second flexible printed circuit FPC2 are disposed by the support portion SUS1 in positions different from each other along the third direction Z. With this structure, the curvatures of the first flexible printed circuit FPC1 and the second flexible printed circuit FPC2 are different from each other. The first circuit element IC1 and the second circuit element IC2 can be separated from each other in the three-dimensional positions. In the space between the first circuit element IC1 and the second circuit element IC2, an air layer AR is disposed. Thus, the heat generated in the first circuit element IC1 and the heat generated in the second circuit element IC2 do not propagate to each other, thereby suppressing the degradation.

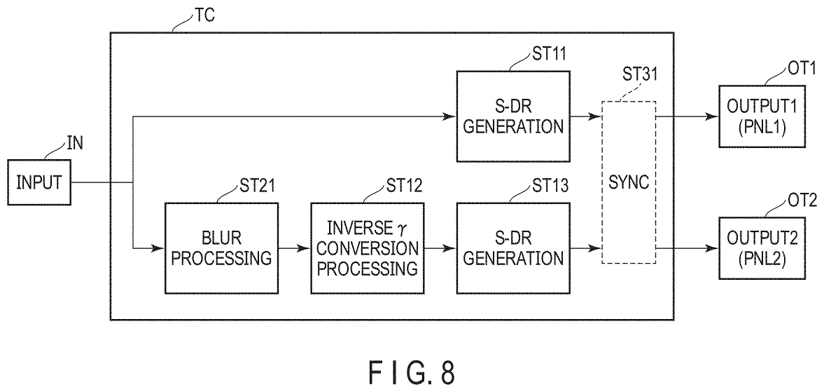

FIG. 8 is a diagram illustrating the function of the wiring board. An input signal (INPUT) IN is input to the wiring board TC. To the dimming panel PNL2, the input signal IN is subjected to an anti-halo blurring process (BLUR PROCESSING) (ST21) and an inverse γ conversion processing (INVERSE γ CONVERSION PROCESSING) (ST22). For the inverse γ conversion process, a look-up table is prepared in advance. Then, the signal generation process (SIGNAL GENERATION) (ST23) is carried out onto the signal line drive circuits of each panel.

On the other hand, for the liquid crystal display panel PNL1, the blurring process and the inverse γ conversion are not carried out, but the signal generation process (SIGNAL GENERATION) (ST11) to the signal line drive circuit is carried out.

The signals generated in the signal generation processes (ST11) and (ST23) may be subjected to a synchronization process (SYNC) (ST31) if necessary. When the synchronization processing is not carried out, the signals generated in the signal generation processes (ST11) and (ST23) are output as an output signal (OUTPUT 1) OT1 and an output signal (OUTPUT 2) OT2, respectively. The output signals OT1 and OT2 are input to the liquid crystal display panel PNL1 and the dimming panel PNL2, respectively. When the synchronization processing is carried out, the synchronized signals are output as output signals OT1 and OT2. Thus, the liquid crystal display panel PNL1 and the dimming panel PNL2 are driven.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a liquid crystal display panel;
a dimming panel;
a first flexible printed circuit connected to the liquid crystal display panel;
a first circuit element provided on the first flexible printed circuit;
a first printed circuit connected to the first flexible printed circuit;
a second flexible printed circuit connected to the dimming panel;
a second circuit element provided on the second flexible printed circuit;
a second printed circuit connected to the second flexible printed circuit;
a frame including a wall portion; and
a support portion including a flat portion and a plurality of leg portions, wherein
the flat portion is provided between the first printed circuit and the second printed circuit,
the wall portion holds and fixes the first flexible printed circuit and the second flexible printed circuit, the first flexible printed circuit and the second flexible printed circuit extending along the wall portion, and
a second curvature of the second flexible printed circuit is smaller than a first curvature of the first flexible printed circuit.

2. The display device according to claim 1, further comprising an air layer disposed between the first circuit element and the second circuit element.

3. The display device according to claim 1, wherein
when the first flexible printed circuit and the second flexible printed circuit are developed in a plane, a short side of the first circuit element and a short side of the second circuit element do not overlap each other.

4. The display device according to claim 1, wherein
when the first flexible printed circuit and the second flexible printed circuit are developed in a plane, a long side of the first circuit element and a long side of the second circuit element do not overlap each other.

5. The display device according to claim 1, wherein
the support portion is formed of a foaming resin material.
